(19) United States
(12) Patent Application Publication
(10) Pub. No.: US 2026/0082597 A1
(43) Pub. Date: Mar. 19, 2026

(54) CAPACITOR, MANUFACTURING METHOD THEREOF, AND MEMORY DEVICE

(71) Applicant: Yangtze Memory Technologies Co., Ltd., Wuhan (CN)

(72) Inventors: Liming TU, Wuhan (CN); Hang ZHOU, Wuhan (CN); Hongxia MA, Wuhan (CN)

(21) Appl. No.: 19/027,784

(22) Filed: Jan. 17, 2025

(30) Foreign Application Priority Data
Sep. 18, 2024 (CN) 202411303761.4

(51) Int. Cl. H10D 1/68; H10B 12/00

(52) U.S. Cl. CPC H10D 1/696; H10B 12/315; H10B 12/482; H10B 12/488; H10D 1/716

(57) ABSTRACT

The examples of the present disclosure provide a capacitor, a manufacturing method thereof and a memory device. The capacitor comprises a dielectric layer, a first electrode and a second electrode located on two sides of the dielectric layer respectively. The first electrode comprises a conductive layer and a buffer layer that are stacked together. A material of the buffer layer comprises an oxide containing indium; and the buffer layer covers at least part of a surface of the conductive layer.

### CROSS-REFERENCE TO RELATED APPLICATIONS

This application claims priority to Chinese Patent Application No. 202411303761.4, filed on Sep. 18, 2024, which is hereby incorporated by reference in its entirety.

### TECHNICAL FIELD

The present disclosure relates to the field of semiconductor technology, and in particular, to a capacitor, a manufacturing method thereof, and a memory device.

### BACKGROUND

A memory device, such as a dynamic random access memory (DRAM), is one of the most important access components in an electronic system, and typically uses one transistor and one capacitor to form a 1T1C structure as a memory cell. Such a 1T1C architecture enables dynamic random access memory to have higher integration and lower cost and play an important role in computer access devices. With the rapid development of semiconductor technology, dynamic random access memory is rapidly developing towards high density and high quality.

### SUMMARY

Examples of the present disclosure provides a capacitor, comprising: a dielectric layer; and a first electrode and a second electrode located on two sides of the dielectric layer respectively, wherein the first electrode comprises a conductive layer and a buffer layer that are stacked together, a material of the buffer layer comprises an oxide containing indium, and the buffer layer covers at least part of a surface of the conductive layer.

In some examples, the buffer layer comprises a first surface and a second surface opposite to each other; the first surface is in contact with the conductive layer; and a roughness of the first surface is less than a roughness of the second surface.

In some examples, the conductive layer has a third surface and a fourth surface opposite to each other; the buffer layer covers at least part of the third surface; and a roughness of the third surface is less than or equal to a roughness of the fourth surface.

In some examples, a material of the buffer layer comprises at least one of indium oxide, indium tin oxide, indium gallium oxide, indium gallium tin oxide, indium zinc oxide, indium gallium zinc oxide, or indium tin zinc oxide.

In some examples, a material of the conductive layer comprises titanium nitride.

In some examples, the first electrode and a connection structure are stacked together; and the buffer layer is located between the connection structure and the conductive layer.

In some examples, the first electrode extends through a supporting layer; and the buffer layer is located between the supporting layer and the conductive layer.

In some examples, the buffer layer is further located between the dielectric layer and the conductive layer.

In some examples, a work function of the buffer layer is higher than a work function of the conductive layer.

In some examples, the first electrode is configured to be coupled to a word line through a transistor.

In some examples, a thickness of the buffer layer ranges from 1 nm to 20 nm.

Examples of the present disclosure further provide a capacitor, comprising: a dielectric layer; and a first electrode and a second electrode located on two sides of the dielectric layer respectively, wherein the first electrode comprises a conductive layer and a buffer layer that are stacked together, the buffer layer has a first surface and a second surface opposite to each other; the first surface is in contact with the conductive layer, and a roughness of the first surface is less than a roughness of the second surface.

In some examples, a material of the buffer layer comprises an oxide containing indium.

In some examples, the conductive layer has a third surface and a fourth surface opposite to each other; the buffer layer covers at least part of the third surface; and a roughness of the third surface is less than or equal to a roughness of the fourth surface.

In some examples, a roughness of a surface of the second electrode is greater than a roughness of a surface of the conductive layer of the first electrode.

Examples of the present disclosure further provide a memory device comprising: a capacitor provided in examples of the present disclosure; and a transistor coupled to the capacitor.

In some examples, the memory device further comprises a connection structure, wherein the connection structure is located between the capacitor and the transistor, and the buffer layer is located between the connection structure and the conductive layer.

In some examples, the memory device further comprises a supporting layer, wherein the first electrode extends through the supporting layer, and the buffer layer is located between the supporting layer and the conductive layer.

In some examples, the supporting layer comprises a plurality of supporting layers stacked together and spaced apart from each other; and the buffer layer is located between the plurality of supporting layers and the conductive layer.

In some examples, the memory device further comprises: a word line and a bit line, wherein a gate of the transistor is coupled to the word line, one of a source and a drain of the transistor is coupled to the first electrode, and the other one of the source and the drain of the transistor is coupled to the bit line.

Examples of the present disclosure further provide a manufacturing method of a capacitor, comprising: forming a dielectric layer; and forming a first electrode and a second electrode located on two sides of the dielectric layer respectively, wherein the first electrode comprises a conductive layer and a buffer layer that are stacked together, a material of the buffer layer comprises an oxide containing indium, and the buffer layer covers at least part of a surface of the conductive layer.

In some examples, forming the first electrode comprises: providing a semiconductor structure, wherein the semiconductor structure comprises a connection structure, a plurality of supporting material layers stacked together and spaced apart from each other on the connection structure, and a filling layer located between two adjacent ones of the plurality of supporting material layers; forming a hole extending through the plurality of supporting material layers and the filling layer, wherein remaining part of the supporting material layers forms the supporting layers; forming a buffer material layer on a side wall and a bottom of the hole, wherein the buffer material layer is configured to form the buffer layer; and forming a conductive layer covering the buffer material layer.

In some examples, forming the buffer material layer on the sidewall and the bottom of the hole comprises: forming the buffer material layer in a crystalline state by using a deposition process at a preset temperature greater than 400° C.

In some examples, forming the dielectric layer comprises: removing remaining part of the filling layer to expose part of the buffer material layer; and depositing a material with a dielectric constant greater than a preset dielectric constant on a side of the first electrode close to the buffer layer to form the dielectric layer, wherein the preset dielectric constant is greater than 3.9.

In some examples, forming the buffer layer comprises: after removing the remaining part of the filling layer, removing exposed part of the buffer material layer, wherein remaining part of the buffer material layer is present between the supporting layer and the conductive layer and between the connection structure and the conductive layer; and forming the buffer layer from the remaining part of the buffer material layer.

In some examples, forming the buffer layer comprises: forming the buffer layer directly from the buffer material layer.

In some examples, forming the second electrode comprises: depositing a conductive material on a side of the dielectric layer away from the first electrode to form the second electrode.

Examples of the present disclosure provides a capacitor, a manufacturing method thereof and a memory device. The capacitor comprises a dielectric layer, a first electrode and a second electrode located on two sides of the dielectric layer respectively. The first electrode comprises a conductive layer and a buffer layer that are stacked together, a material of the buffer layer comprises an oxide containing indium, and the buffer layer covers at least part of a surface of the conductive layer. In the examples of the present disclosure, by forming a material comprising the oxide containing indium with small particle size, concaves on the rough surface can be well filled before forming the conductive layer stacked on the buffer layer, so that the conductive layer has a small surface roughness. The conductive layer with a small surface roughness is conducive to optimizing the equivalent circuit of the capacitor electrode, thereby improving the electric leakage problem of the capacitor.

### BRIEF DESCRIPTION OF THE DRAWINGS

FIG. 1 is a schematic diagram of a structure of a dynamic random access memory according to examples of the present disclosure;

FIG. 2A to FIG. 2H are schematic diagram I of cross-sectional structure of a capacitor in a manufacturing process according to examples of the present disclosure;

FIG. 3 is a schematic flow diagram of a method for manufacturing a capacitor according to examples of the present disclosure;

FIG. 4A to FIG. 4J are schematic diagram II of cross-sectional structure of a capacitor in a manufacturing process according to examples of the present disclosure;

FIG. 5A to FIG. 5D are schematic diagrams of the principle of reducing roughness of a surface by adding a buffer material layer according to examples of the present disclosure;

FIG. 6A to FIG. 6B are schematic diagrams of the effect of two different surface roughness on an electric leakage model according to examples of the present disclosure;

FIG. 7 is a schematic diagram of leakage current and electric field curves of a capacitor in a high field region according to examples of the present disclosure;

FIG. 8A is a schematic diagram of a layout of a connection structure comprising a capacitor according to examples of the present disclosure;

FIG. 8B is a partial enlarged view corresponding to the dashed box in FIG. 8A;

FIG. 9 is a schematic diagram of a connection relationship between a capacitor and a word line according to examples of the present disclosure.

In the above figures, which are not necessarily drawn to scale, like reference numerals may describe like components in different views. Like reference numbers with different letter suffixes may represent different examples of like components. The drawings generally illustrate various examples discussed herein by way of example rather than limitation.

### DETAILED DESCRIPTION

Example implementations disclosed in the present disclosure will be described in more detail below with reference to the accompanying drawings. Although example implementations of the present disclosure are shown in the accompanying drawings, it is to be understood that the present disclosure may be implemented in various forms and should not be limited by the specific examples set forth in some examples. Rather, these examples are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual example are described some examples, and well-known functions and structures are not described in detail.

In the drawings, the sizes of layers, regions, elements, and their relative sizes may be exaggerated for clarity. Like reference numbers refer to like elements throughout the drawings.

It should be understood that spatial relation terms such as “beneath,” “below,” “lower,” “under”, “over,” “upper,” etc., may be used in some examples for ease of description to describe the relationship between one element or feature and other elements or features shown in the figures. It should be understood that in addition to the orientations shown in the figures, the spatial relation terms intend to also comprise different orientations of the devices in use and operation. For example, if the device in the figure is flipped, then the device described as “below” or “under” or “beneath” other elements or features will be oriented “on” other elements or features. Thus, the example terms “below” and “under” may comprise both upper and lower orientations. The devices may be additionally oriented (rotated 90 degrees or other orientations) and the spatial description terminology used herein is interpreted accordingly.

Terms used herein are for the purpose of describing a particular example only and are not to be considered as limitation of the present disclosure. As used herein, the singular forms “a”, “an” and “the” are intended to comprise the plural forms as well, unless the context clearly indicates otherwise. It should also be understood that the terms “consists of” and/or “comprising”, when used in this description, determine the presence of stated features, integers, steps, operations, elements and/or parts, but do not exclude the presence or addition of one or more other features, integers, steps, operations, elements, parts and/or groups. As used herein, the term “and/or”comprises any and all combinations of the associated listed items.

For a more detailed understanding of the features and technical contents of the examples of the present disclosure, the implementations of the examples of the present disclosure are described in detail below with reference to the accompanying drawings, and the accompanying drawings are for illustrative purposes only and are not intended to limit the examples of the present disclosure.

As the integration level of the memory device becomes increasingly higher, the size of the capacitor constituting the memory device is continuously decreasing, and as its size decreases, the manufacturing process of capacitor becomes more difficult, and the thin film thickness of each functional layer in the capacitor also becomes thinner, thereby the electric leakage problem of the capacitor becomes more significant.

In some examples, the memory device uses an open bit line structure. Compared to a stacked bit line structure, the actual size of the capacitor hole in the open bit line structure is smaller, so that crosstalk between adjacent capacitors becomes serious, and there is a higher requirement on electric leakage.

It should be noted that the capacitor in the examples of the present disclosure may be applied to a memory device, or may be also applied to other semiconductor devices, which is not limited by the examples of the present disclosure. In the following, applying the capacitor in the memory device is taken as an example. The memory device in the examples of the present disclosure comprises, but is not limited to, a dynamic random access memory, and the dynamic random access memory is taken as an example for description below.

In some examples of the present disclosure, no matter whether the transistor is a planar transistor or a buried transistor, the dynamic random access memory is composed of a plurality of memory cells, and each of the memory cells is composed of a transistor and a capacitor controlled by the transistor, that is, the dynamic random access memory comprises an architecture of one transistor (T) and one capacitor (C) (1T1C); and its main operation principle is to use the amount of the charges stored in the capacitor to represent whether one binary bit is 1 or 0.

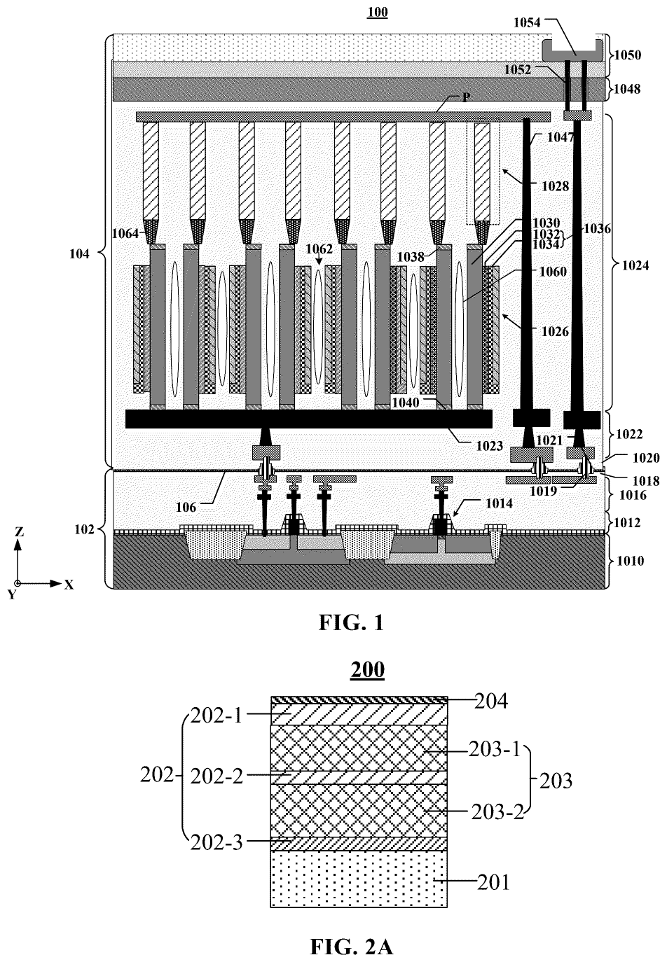

One of the architectures of the dynamic random access memory is described in detail below with reference to FIG. 1. Before introducing the memory device illustrated in FIG. 1, various directions that may be used in the following description are defined. The extension direction of the semiconductor body is defined as the first direction (i.e., the Z-axis direction). The intersecting second direction (i.e., the X-axis direction) and the third direction (i.e., the Y-axis direction) are defined in a plane perpendicular to the Z-axis direction. In some examples, the X-axis direction, the Y-axis direction, and the Z-axis direction may be perpendicular to each other.

A cross-sectional view of a three-dimensional (3D) dynamic random access memory 100 comprising vertical transistors is provided in examples of the present disclosure. As shown in FIG. 1, the dynamic random access memory 100 comprises a first device 102 and a second device 104 stacked on the first device 102 along the Z-axis direction, and the first device 102 and the second device 104 are connected through a bonding interface 106. The first device 102 and the second device 104 may be connected in a hybrid bonding manner, etc. In some examples, the second device 104 may be bonded on top of the first device 102 in a face-to-face manner at the bonding interface 106. The first device 102 may comprise a first substrate 1010, a peripheral circuit 1012 located on a side of the first substrate 1010, and a first interconnection layer 1016 located on a side of the peripheral circuit 1012 away from the first substrate 1010. The first interconnection layer 1016 is configured to transmit an electrical signal of the peripheral circuit 1012. The peripheral circuit 1012 may comprise a plurality of transistors 1014. In some examples, trench isolation (e.g., shallow trench isolation (STI)) and doped regions (e.g., well, source, and drain of transistor 1014) may also be formed on or in the first substrate 1010.

The first device 102 may further comprise a first bonding layer 1018 at the bonding interface 106 and on a side of the first interconnection layer 1016 away from the peripheral circuit 1012. The first bonding layer 1018 may comprise a plurality of first bonding contacts 1019 and a dielectric electrically isolating the first bonding contacts 1019. The first bonding contact 1019 and the surrounding dielectric in the first bonding layer 1018 may be used for hybrid bonding. Correspondingly, the second device 104 may also comprise a second bonding layer 1020 at the bonding interface 106 and located on a side of the first bonding layer 1018 away from the first interconnection layer 1016. The second bonding layer 1020 may comprise a plurality of second bonding contacts 1021 and a dielectric electrically isolating the second bonding contacts 1021. The second bonding contact 1021 and the surrounding dielectric in the second bonding layer 1020 may be used for hybrid bonding. In some examples, the second bonding contact 1021 is in contact with the first bonding contact 1019 at the bonding interface 106.

In some examples, the peripheral circuit 1012 may further comprise a word line driver/row decoder coupled to a word line (WL) in the second interconnection layer 1022 through the second bonding contact 1021 in the second bonding layer 1020 and the first bonding contact 1019 in the first bonding layer 1018 and the first interconnection layer 1016. In some other examples, the peripheral circuit 1012 may further comprise a bit line driver/column decoder coupled to the bit line 1023 (BL) in the second interconnection layer 1022 through the second bonding contact 1021 in the second bonding layer 1020 and the first bonding contact 1019 in the first bonding layer 1018 and the first interconnection layer 1016. In some examples, the second interconnection layer 1022 comprises a bit line 1023 above the second bonding layer 1020 for transmitting electrical signals. In some other examples, the stacked first device 102 and the second device 104 may not be connected by bonding, but are integrated on the same substrate (only the first substrate, and not the second substrate), and are directly connected through one or more interconnection layers between the first device 102 and the second device 104. In this case, the first bonding layer 1018 and the first bonding contact 1019 are not present in the first device 102; the second bonding layer 1020 and the second bonding contact 1019 are not present in the second device 104; and the bonding interface 106 between the first device 102 and the second device 104 is also not present.

Referring to FIG. 1, the second device 104 further comprises an array of memory cells on the second interconnection layer 1022. The array of memory cells may comprise a plurality of memory cells 1024, a second substrate 1048 on the memory cells 1024, and a third interconnection layer 1050 on the second substrate 1048. The cross section of the dynamic random access memory 100 in FIG. 1 may be taken along the bit line direction (X-axis direction), and one bit line 1023 in the second interconnection layer 1022 extending laterally in the X-axis direction may be coupled to a column of memory cells 1024.

In some examples, each memory cell 1024 may comprise a vertical transistor 1026 and a capacitor 1028 coupled to the vertical transistor 1026. The vertical transistor 1026 comprises a semiconductor body 1030 extending vertically (in the Z-axis direction), and a gate structure 1036 in contact with one side of the semiconductor body 1030 in the bit line direction (X-axis direction). In some other examples, the gate structure may also fully surround the semiconductor body, semi-surround the semiconductor body, be located on two opposite sides of the semiconductor body, and the like, which will not be detailed here. In some examples, the gate structure 1036 comprises a gate electrode 1034 and a gate dielectric 1032 located between the gate electrode 1034 and the semiconductor body 1030 in the bit line direction (X-axis direction). In some examples, the gate dielectric 1032 adjoins one side of the semiconductor body 1030, and the gate electrode 1034 adjoins the gate dielectric 1032.

In some examples, the semiconductor body 1030 has two ends (upper end and lower end) in the vertical direction (Z-axis direction), and one end (such as the lower end in FIG. 1) extends beyond the gate dielectric 1032 into an interlayer dielectric (ILD) layer in the vertical direction (Z-axis direction), and the other end (such as the upper end in FIG. 1) of the semiconductor body 1030 is flush with the corresponding end of the gate dielectric 1032. In some other examples, the two ends (upper end and lower end) of the semiconductor body 1030 extend beyond the gate electrode 1034 into the ILD layer in the vertical direction (Z-axis direction), respectively. In other words, the semiconductor body 1030 may have a larger vertical dimension (e.g., depth in the Z-axis direction) than that of the gate electrode 1034, and neither the upper end nor the lower end of the semiconductor body 1030 is flush with the corresponding end of the gate electrode 1034. As such, a short circuit between the bit line 1023 and the word line/gate electrode 1034 or between the word line/gate electrode 1034 and the capacitor 1028 may be avoided.

The vertical transistor 1026 may further comprise a source 1038 and a drain 1040 disposed at two ends (upper end and lower end) of the semiconductor body 1030 respectively in the vertical direction (Z-axis direction). The positions of the source and the drain may be interchanged, and the upper end is the source 1038 and the lower end is the drain 1040 as an example here and below. In some implementations, the source 1038 is coupled to the capacitor 1028, and the drain 1040 is coupled to the bit line 1023.

Since the gate electrode may be part of a word line or extend as a word line in the word line direction, the second device 104 of the dynamic random access memory 100 may also comprise a plurality of word lines extending in a word line direction (Y-axis direction). In some examples, each word line 1034 may be coupled to a row of memory cells 1024.

The vertical transistor 1026 extends vertically through the word line 1034 and is in contact with the word line 1034, and is in contact with the bit line 1023 at the drain 1040 at its lower end. Thus, due to the vertical arrangement of vertical transistors 1026, the word line 1034 and bit line 1023 may be disposed in different planes in the vertical direction, which simplifies the routing of word line 1034 and bit line 1023. In some examples, the vertical transistors 1026 may be arranged in mirror symmetry to increase the density of the memory cells 1024 in the bit line direction (X-axis direction). Two adjacent vertical transistors 1026 in the bit line direction are mirror symmetric to each other with respect to the trench isolation 1060, that is, the second device 104 may comprise a plurality of trench isolations 1060, and each trench isolation 1060 extends in a word line direction (Y-axis direction) parallel to the word line 1034 and is between two adjacent rows of semiconductor bodies 1030 of the vertical transistor 1026. In some implementations, rows of vertical transistors 1026 separated by trench isolation 1060 are mirror symmetric to each other with respect to trench isolation 1060. It should be understood that trench isolation 1060 may comprise air gaps, each of which is disposed laterally between adjacent semiconductor bodies 1030. The second device 104 further comprises a plurality of gate isolation 1062, each of which extends in a word line direction (Y-axis direction) parallel to the word line 1034 and is between two adjacent rows of word lines 1034 of the vertical transistor 1026. It should be understood that the size of the gate isolation 1062 and the word line 1034 in the bit line direction (X-axis direction) and the size of the trench isolation 1060 in the bit line direction (X-axis direction) may be the same or different; and when their sizes in the bit line direction (X-axis direction) are different, the spacings between the plurality of semiconductor bodies 1030 arranged along the bit line direction (X-axis direction) are different, that is, the plurality of semiconductor bodies 1030 arranged along the bit line direction (X-axis direction) may have a non-uniform arrangement.

As shown in FIG. 1, the capacitor 1028, which may be a vertical capacitor, is above and in contact with the source 1038 of the vertical transistor 1026 (i.e., the upper end of the semiconductor body 1030).

In some implementations, a conductive structure 1064 is formed between the capacitor 1028 and the vertical transistor 1026 to reduce contact resistance.

As shown in FIG. 1, the second device 104 may further comprise a capacitor contact 1047 in contact with the common plate P of the capacitor 1028 for coupling one electrode of the capacitor 1028 to the peripheral circuit 1012 or directly to ground. In some implementations, the ILD layer forming the capacitor 1028 has the same dielectric material (e.g., silicon oxide) as the two ILD layers into which the semiconductor body 1030 extends. The configuration of the capacitor 1028 may comprise any suitable structure and configuration, such as planar capacitors, stack capacitors, multi-fin capacitors, cylinder capacitors, trench capacitors, or substrate-plate capacitors.

As shown in FIG. 1, vertical transistor 1026 extends vertically through word line 1034 and is in contact with the word line 1034, is in contact with the bit line 1023 at drain 1040 at its lower end, and is in contact with the capacitor 1028 at source 1038 at its upper end. That is, due to the vertical arrangement of the vertical transistors 1026, the bit line 1023 and the capacitor 1028 may be disposed in different planes in the vertical direction and coupled to opposite ends of the vertical transistors 1026 of the memory cells 1024 in the vertical direction. In some implementations, the bit line 1023 and the capacitor 1028 are disposed on opposite sides of the vertical transistor 1026 in the vertical direction, which simplifies routing of the bit line 1023 and reduces the coupling capacitance between the bit line 1023 and the capacitor 1028 as compared to conventional memory cells in which the bit line and the capacitor are disposed on the same side of the planar transistor.

In some examples, the vertical transistor 1026 is vertically disposed between the capacitor 1028 and the bonding interface 106. That is, the vertical transistor 1026 may be arranged closer to the peripheral circuit 1012 and the bonding interface 106 of the first device 102 than the capacitor 1028. Since the bit line 1023 and capacitor 1028 are coupled to opposite ends of the vertical transistor 1026, the bit line 1023 (as part of the second interconnection layer 1022) is vertically disposed between the vertical transistor 1026 and bonding interface 106 to reduce interconnection routing distance and complexity.

In some examples, the second device 104 further comprises a second substrate 1048 disposed above the memory cell 1024, and a pad-out third interconnection layer 1050 disposed above the memory cell 1024. The pad-out third interconnection layer 1050 may comprise interconnect structures in one or more ILD layers, e.g., contact pads 1054.

In some examples, the second device 104 further comprises one or more contacts 1052 extending through part of the pad-out third interconnection layer 1050 and the second substrate 1048 to couple the pad-out third interconnection layer 1050 to the memory cell 1024 and the second interconnection layer 1022. As such, the peripheral circuit 1012 may be coupled to the memory cell 1024 through the first interconnection layer 1016 and the second interconnection layer 1022 and the second bonding layer 1020 and the first bonding layer 1018, and the peripheral circuit 1012 and the memory cell 1024 may be coupled to an external circuit through the contact 1052 and the pad-out third interconnection layer 1050.

Examples of the present disclosure provides a manufacturing method of a capacitor 1028, where the capacitor comprises a first electrode, a dielectric layer, and a second electrode; and the manufacturing method comprises:

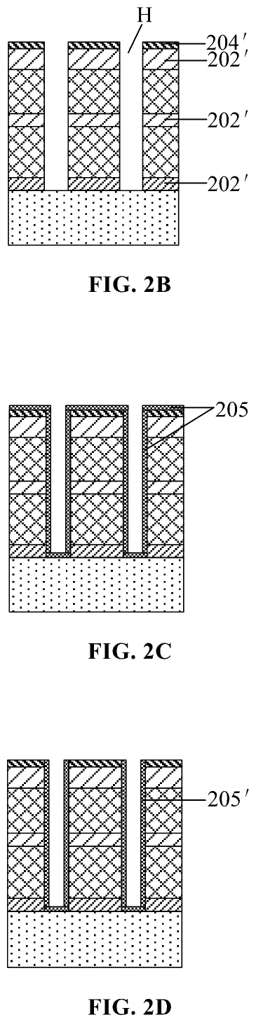

S1: as shown in FIG. 2A, a semiconductor structure 200 is provided. The semiconductor structure 200 comprises a semiconductor layer 201, a plurality of supporting material layers 202 stacked together and spaced apart from each other on a side of the semiconductor layer 201, and a filling layer 203 located between two adjacent supporting material layers 202.

In some examples, the semiconductor layer 201 may comprise an elementary semiconductor material (e.g., a silicon (Si) substrate, a germanium (Ge) substrate, etc.), a III-V compound semiconductor material (e.g., a gallium nitride (GaN) substrate, etc.), an organic semiconductor material, or other semiconductor materials known in the art, and may also comprise other substrates containing semiconductor material, such as silicon-on-insulator (SOI) substrates, etc. The semiconductor layer 201 may be doped, undoped, or comprise both a doped region and an undoped region therein. In some examples, the material of the semiconductor layer 201 comprises silicon.

In some examples, the material of the plurality of supporting material layers 202 and the material of the filling layer 203 have distinctive etching selectivity, and the materials of the supporting material layers 202 and the filling layer 203 may be different.

In some examples, the plurality of supporting material layers 202 may comprise a first supporting material layer 202-1, a second supporting material layer 202-2, and a third supporting material layer 202-3, and materials of the plurality of supporting material layers may be the same or different. For example, the material of the first supporting material layer 202-1 and the material of the second supporting material layer 202-2 may comprise silicon carbon nitride (SiCN), and the material of the third supporting material layer 202-3 may comprise silicon boron nitride (SiBN).

In some examples, the filling layer 203 may comprise a first filling layer 203-1 between the first supporting material layer 202-1 and the second supporting material layer 202-2, and a second filling layer 203-2 between the second supporting material layer 202-2 and the third supporting material layer 202-3. For example, the material of the first filling layer 203-1 comprises tetraethyl orthosilicate (TEOS), and the material of the second filling layer comprises boro-phospho-silicate glass (BPSG).

In some examples, the semiconductor structure 200 may further comprise an insulating material layer 204 located on one side of the plurality of supporting material layers 202 away from the semiconductor layer 201, and a material of the insulating material layer 204 comprises, but is not limited to, silicon nitride.

S2: as shown in FIG. 2B, a hole H extending through the plurality of supporting material layers 202 and the filling layer 203 is formed; and the remaining supporting material layer forms a supporting layer 202′.

In some examples, part of the supporting material layer 202 and part of the filling layer 203 may be removed by a dry etching process to form the hole H.

In some examples, the semiconductor structure 200 may further comprise an insulating material layer 204, and while the part of the supporting material layer 202 and the part of the filling layer 203 are removed to form the hole H, part of the insulating material layer 204 is simultaneously removed, and the remaining insulating material layer forms the insulating layer 204′.

S3: as shown in FIG. 2C, forming a conductive material layer 205 on the top surface of the semiconductor structure, the side surface and the bottom of the hole H.

In some examples, the conductive material layer 205 serves as a first electrode of a capacitor, and the conductive material layer 205 comprises, but is not limited to, titanium nitride (TiN). In some examples, the semiconductor structure 200 comprises an insulating material layer 204, and the conductive material layer 205 covers a side of the insulating material layer 204 away from the semiconductor layer 201.

S4: as shown in FIG. 2D, removing part of the conductive material layer 205 on the top surface of the semiconductor structure 200 to form the first electrode 205′ of the capacitor.

In some examples, the part of the conductive material layer 205 may be removed by a dry etching process to form the first electrode 205′.

S5: as shown in FIG. 2E, forming a filling structure 206 in the hole formed with the first electrode 205′.

In some examples, the initial filling structure may be formed in the hole and the top surface of the semiconductor structure 200 by various deposition processes, such as a chemical vapor deposition process, and part of the initial filling structure located on the top surface of the conductive structure 200 may be removed by a chemical mechanical polishing process to obtain the filling structure. It can be understood that the above-mentioned insulating layer 204 may serve as a stop layer for the chemical mechanical polishing, thereby achieving a better protection effect on the supporting layer 202′.

S6: as shown in FIG. 2F, removing the remaining filling layer to expose part of a surface of the first electrode 205′.

In some examples, after the remaining filling layer is removed, the part of the surface of the first electrode 205′ in contact with the remaining filling layer is exposed while the surface of the supporting layer 202′ in contact with the remaining filling layer is also exposed. In addition, the part of the surface of the first electrode 205′ in contact with the supporting layer and the semiconductor layer is not exposed.

In some examples, a trench T through the insulating layer 204′ and the supporting layer 202′ may be formed, and the remaining filling layer may be removed in the trench T by a wet etching process. The filling layer has a high volume in the whole semiconductor structure, and in the process of removing the remaining filling layer, the supporting layer 202′ and the filling structure 206 may both provide good support.

S7: as shown in FIG. 2G, forming a dielectric layer 207 of a capacitor on a side of the first electrode 205′.

In some examples, the dielectric layer 207 may be conformal to the structure after the filling layer is removed, that is, the dielectric layer 207 may cover the exposed surface of the first electrode 205′ and the exposed surface of the supporting layer. As such, a larger surface area of the dielectric layer can be obtained, thereby facilitating obtaining a larger capacitance capacity.

In some examples, the dielectric layer has a dielectric constant greater than 3.9. For example, the material of the dielectric layer may comprise one or more of aluminum oxide (Al₂O₃), zirconium oxide (ZrO₂), and hafnium oxide (HfO₂).

In some examples, the dielectric layer 207 may be formed by a deposition process, such as an atomic layer deposition process.

S8: as shown in FIG. 2H, forming a second electrode 208 of a capacitor on a side of the dielectric layer 207 away from the first electrode 205′.

In some examples, the second electrode 208 may cover a side of the dielectric layer 207 away from the first electrode 205′, and the second electrode may have an irregular shape, for example, the second electrode may fill the entire void space regions of the semiconductor structure after the filling layer is removed and the dielectric layer is formed. As such, the capacitor may obtain a larger capacitance capacity.

In some examples, the material of the second electrode 208 may comprise, but is not limited to, tungsten. In some examples, the material forming the second electrode 208 may comprise silicon germanium (SiGe) and tungsten. In some examples, the second electrode 208 may be formed by a deposition process.

In the above examples of the present disclosure, forming the first electrode has a simple process and low manufacturing cost.

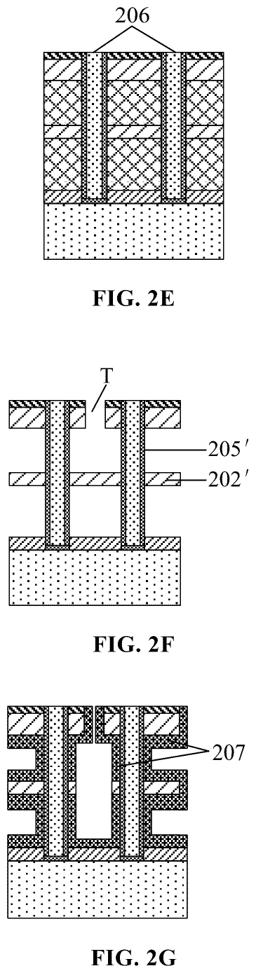

Examples of the present disclosure provides another manufacturing method of a capacitor. As shown in FIG. 3, the manufacturing method comprises:

S11: forming a dielectric layer.

S12: forming a first electrode and a second electrode. The first electrode and the second electrode are located on two sides of the dielectric layer respectively; the first electrode comprises a conductive layer and a buffer layer that are stacked together; a material of the buffer layer comprises an oxide containing indium; and the buffer layer covers at least part of a surface of the conductive layer.

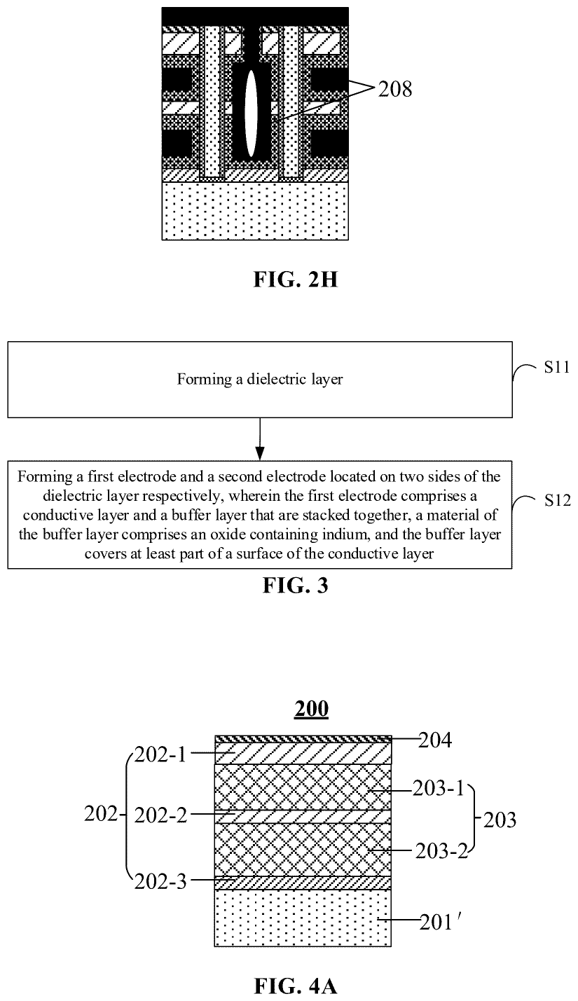

It should be understood that the steps shown in FIG. 3 are not exclusive, and other steps may be performed before, after, or between any steps in the illustrated operations; the sequence of steps shown in FIG. 3 may be adjusted according to actual needs. The method for forming the capacitor includes a plurality of methods, a few of which are shown in the examples of the present disclosure. FIG. 4A to FIG. 4J are schematic diagrams of cross-section of a process of forming a capacitor according to examples of the present disclosure. The process of forming the capacitor is described in detail below with reference to FIG. 3 and FIG. 4A to FIG. 4J.

In the process of performing S11 and S12, in some examples, forming the first electrode comprises: providing a semiconductor structure, wherein the semiconductor structure comprises a connection structure, a plurality of supporting material layers stacked together and spaced apart from each other on the connection structure, and a filling layer located between two adjacent supporting material layers; forming a hole extending through the plurality of supporting material layers and the filling layer; forming a supporting layer with the remaining supporting material layer; forming a buffer material layer on a side wall and a bottom of the hole, wherein the buffer material layer is configured to form the buffer layer; and forming a conductive layer covering the buffer material layer.

For example, as shown in FIG. 4A, a semiconductor structure 200 is provided. The semiconductor structure 200 comprises a connection structure 201′, a plurality of supporting material layers 202 (three supporting material layers, i.e., a first supporting material layer 202-1, a second supporting material layer 202-2, and a third supporting material layer 202-3 are shown in FIG. 4A) stacked together and spaced apart from each other on the connection structure 201′, and a filling layer 203 (two filling layers, i.e., a first filling layer 203-1 and a second filling layer 203-2 are shown in FIG. 4A) located between two adjacent supporting material layers. The structure of the semiconductor structure 200 may be understood with reference to the related structure of the semiconductor structure 200 in the capacitor 1028 in the above-mentioned examples.

It should be noted that, the connection structure 201′ in some examples may be understood with reference to the semiconductor layer 201 in the above-mentioned examples, except that the connection structure 201′ in some examples has better electrical connection performance, and the connection structure 201′ may be used to form the above-mentioned conductive structure 1064.

Next, as shown in FIG. 4B, a hole H extending through the plurality of supporting material layers 202 and the filling layer 203 is formed. The implementation in FIG. 4B may be understood with reference to FIG. 2B, which will not be detailed here.

Next, as shown in FIG. 4C, a buffer material layer 301 is formed on the sidewalls and the bottom of the hole H. In some examples, the initial buffer material layer 301′ is formed on the top surface of the semiconductor structure and on the sides and the bottom of the hole H.

Next, as shown in FIGS. 4D and 4E, a conductive layer 302 covering the initial buffer material layer 301′ is formed.

As shown in FIG. 4D, a conductive material layer 205 is formed on the exposed surface of the initial buffer material layer 301′. In some examples, the conductive material layer 205 serves as a conductive layer of the first electrode of the capacitor, and the conductive material layer 205 comprises, but is not limited to, titanium nitride (TiN).

As shown in FIG. 4E, part of the initial buffer material layer 301′ and part of the conductive material layer 205 located on the top surface of the semiconductor structure are removed, wherein the remaining conductive material layer forms the conductive layer 302 of the first electrode of the capacitor, and the remaining initial buffer material layer 301′ forms the buffer material layer 301. In some examples, the part of the buffer material layer and the part of the conductive material layer may be removed by a dry etching process.

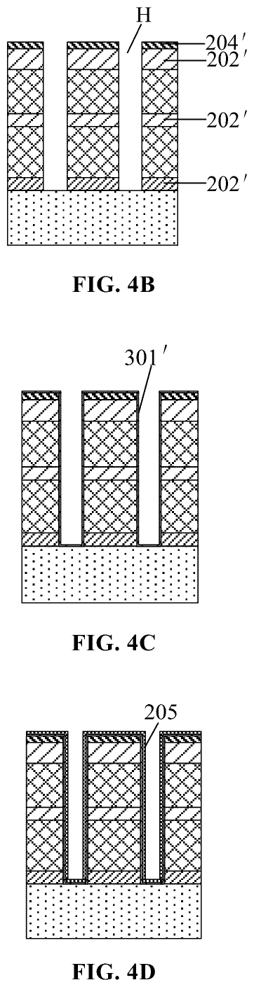

According to the examples of the present disclosure, the buffer material layer added before the growth of the conductive layer has a small particle size, and concaves on the rough surface can be well filled before forming the conductive layer, so that a conductive layer with low surface roughness is formed. FIG. 5A to FIG. 5D are schematic diagrams of the principle of reducing surface roughness by adding a buffer material layer according to examples of the present disclosure.

As shown in FIG. 5A, a dielectric material layer 402 (similar to the filling layer 203 described above) is formed on a side of a semiconductor material layer 401 (similar to the semiconductor layer 201 or the connection layer 201′ described above). For example, a material of the semiconductor material layer 401 may comprise silicon, and a material of the dielectric material layer 402 may comprise an oxide, such as silicon oxide. It should be noted that the dielectric material layer 402 has a high growth rate, and it has a large surface roughness.

As shown in FIGS. 5B and 5C, a transition layer 403 (similar to the buffer material layer 301 described above) is formed on a side of the dielectric material layer 402 away from the semiconductor material layer 401. In the process of forming the transition layer 403, the transition material layer 403′ may be firstly formed by a deposition process, and then the transition material layer 403′ may undergo a heat treatment at a temperature greater than 400° C., so that the transition material layer 403′ is crystallized to obtain the transition layer 403.

In some examples, a material of the transition material layer 403′ comprises at least one of indium oxide, indium tin oxide, indium gallium oxide, indium gallium tin oxide, indium zinc oxide, indium gallium zinc oxide, or indium tin zinc oxide. The oxide comprising indium has a small particle size, so that the surface of the dielectric material layer 402 can be well filled, and the side of the transition material layer 403′ away from the dielectric material layer 402 has a higher flatness and a smaller surface roughness. The effect of this filling is further improved after crystallization of the transition material layer 403′.

Based on this, as shown in FIG. 5C, the transition layer 403 comprises a first surface S1 and a second surface S2 opposite to each other; the first surface S1 is in contact with a conductive functional layer 404 to be generated subsequently (shown in FIG. 5D), and the second surface is in contact with the dielectric material layer 402; and a roughness of the first surface S1 is less than a roughness of the second surface S2. In some examples, a difference between the roughness of the second surface and the roughness of the first surface is greater than a first preset difference. In some examples, a range of the first preset difference is: 0.3-0.5 nm. For example, the first preset difference is 0.3 nm, 0.4 nm, or 0.5 nm.

As shown in FIG. 5D, a conductive functional layer 404 (similar to the conductive layer 302 described above) is formed on a side of the transition layer 403 away from the dielectric material layer 402. Since the surface roughness of the first surface S1 of the transition layer 403 is low, the surface roughness of the third surface S3 of the conductive layer 404 in contact with the first surface is lower than or equal to that of the subsequently formed fourth surface S4 opposite to the third surface. In some examples, a difference between a roughness of the fourth surface and a roughness of the third surface is greater than a second preset difference, and the second preset difference may be the same as or slightly less than the first preset difference. In some examples, a range of the second preset difference is: 0.2-0.4 nm. For example, the preset difference is 0.2 nm, 0.3 nm, or 0.4 nm.

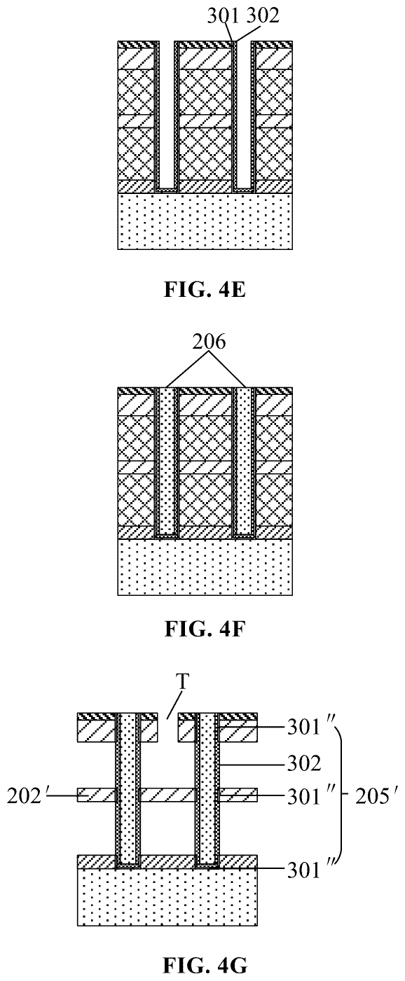

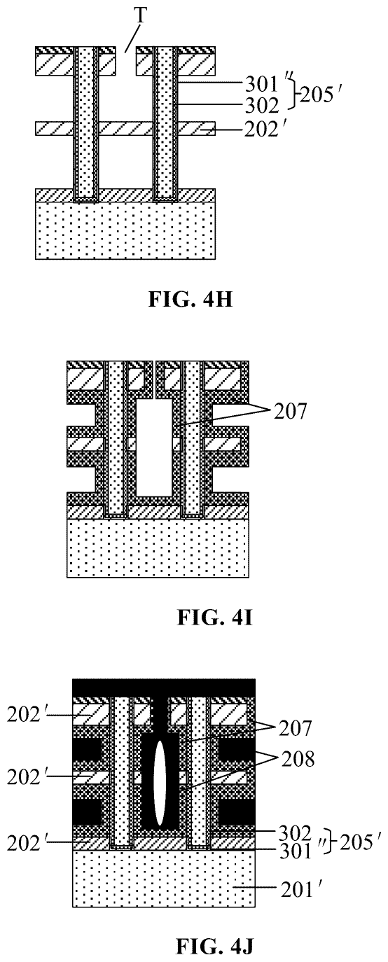

FIG. 6A to FIG. 6B are schematic diagrams of the effect of two different surface roughness on a leakage model according to examples of the present disclosure. FIG. 7 is a schematic diagram of leakage current and electric field curves of a capacitor in a high field region according to examples of the present disclosure.

As can be seen from FIG. 7, the leakage current and the electric field curve of the capacitor in the high field region are represented by two back-to-back Schottky diodes D1 and D2 (SE) that have two different Schottky barrier heights and are in series with a nonlinear resistor (PF). In combination with FIG. 6A and FIG. 6B, the conductive layer has a large surface roughness, which is approximately equivalent to forming a group of reverse Schottky diodes at the interface of the dielectric layer according to the electric leakage model, and these reverse Schottky diodes result in a large leakage current of the capacitor. Based on this, the conductive functional layer with a small surface roughness may improve the electric leakage problem.

Based on the above analysis, the effect of the transition layer on the roughness of the conductive function layer may be applied to the buffer layer (buffer material layer) in the examples of the present disclosure to reduce the surface roughness of the conductive layer through the buffer layer, and achieve the purpose of improving the leakage current of the capacitor.

In some examples, a material of the buffer material layer 301 comprises at least one of indium oxide, indium tin oxide, indium gallium oxide, indium gallium tin oxide, indium zinc oxide, indium gallium zinc oxide, or indium tin zinc oxide. In some examples, the material of the buffer material layer 301 comprises indium oxide.

In some examples, forming the buffer material layer 301 at the sidewall and the bottom of the hole comprises: forming the buffer material layer 301 in a crystalline state at a preset temperature greater than 400° C. by using a deposition process. It can be understood that after the buffer material layer is crystallized, the effect of the filling is further improved, and the surface roughness of the subsequently formed conductive layer 302 is further reduced.

In the examples of the present disclosure, a buffer layer, such as indium oxide, is firstly formed before the growth of the conductive layer of the first electrode, and then a conductive layer, such as titanium nitride, is formed on the buffer layer. The crystalline compound containing indium oxide has a small particle size, and concaves on the rough surface can be well filled before forming the conductive layer stacked on the buffer layer, so that the conductive layer has a small surface roughness.

In the examples of the present disclosure, the thickness of the buffer material layer 301 needs to reach a certain thickness, so that the rough surface of the filling layer can be fully filled. However, the thickness of the buffer material layer 301 should not be too thick, i.e., should not exceed the radius of the capacitor hole (i.e., H described above) of the capacitor, and the capacity of the capacitor will be affected if the thickness of the buffer material layer 301 is too large. A relatively ideal thickness is the thinnest thickness capable of fully filling the rough surface of the filling layer. In some examples, a thickness of the buffer material layer ranges from 1 nm-20 nm. For example, the buffer material layer has a thickness of 1 nm, 2 nm, 3 nm, 4 nm, 5 nm, 10 nm, 15 nm, or 20 nm.

In some examples, in the subsequent process of removing the filling layer, part of indium oxide on the sidewall of the titanium nitride is cleaned away by acid, so that titanium nitride with a smooth surface roughness is left on the sidewall.

Next, a dielectric layer of the capacitor is formed. In some examples, forming the dielectric layer comprises: removing the remaining filling layer to expose part of the buffer material layer; and depositing a material with a dielectric constant greater than a preset dielectric constant on a side of the first electrode close to the buffer layer to form the dielectric layer, wherein the preset dielectric constant is greater than 3.9.

Still referring to FIG. 4A to FIG. 4J, as shown in FIG. 4F, a filling structure 206 is formed in the hole with the conductive layer 302 formed before the dielectric layer. In some examples, the initial filling structure may be formed in the hole and the top surface of the semiconductor structure 200 by various deposition processes, such as a chemical vapor deposition process, and part of the initial filling structure located on the top surface of the conductive structure 200 may be removed by a chemical mechanical polishing process to obtain the filling structure. It can be understood that the insulating layer 204 described above can be used as a stop layer for the chemical mechanical polishing, thereby achieving a better effect of protection on the supporting layer 202′.

Next, at least the remaining filling layer is removed.

In some examples, after the remaining filling layer is removed, the part of the surface of the buffer material layer 310 in contact with the remaining filling layer is exposed while the supporting layer 202′ in contact with the remaining filling layer is exposed. In addition, the part of the surface of the buffer material layer 310 in contact with the supporting layer, the insulating layer, and the connection structure 201′ is not exposed.

In some examples, a trench T extending through the insulating layer 204′ and the supporting layer 202′ may be formed, and the remaining filling layer may be removed in the trench T by a wet etching process. The filling layer has a high volume in the entire semiconductor structure, and in the process of removing the remaining filling layer, the supporting layer 202′ and the filling structure 206 may both provide good support.

It should be noted that, after the remaining filling layer is removed, the exposed buffer material layer 310 may be selectively removed.

In some examples, as shown in FIG. 4G, after the remaining filling layer is removed, the exposed part of the buffer material layer is removed; the remaining buffer material layer is present between the supporting layer and the conductive layer and between the connection structure and the conductive layer; and the remaining buffer material layer forms a buffer layer 301′.

In some examples, the exposed buffer material layer 310 is removed, and only the unexposed part of the buffer material layer between the supporting layer and the conductive layer and between the connection structure and the conductive layer is retained. In this case, the buffer layer is located between the connection structure and the conductive layer, while the buffer layer is also located between the supporting layer and the conductive layer. It can be understood that the material of the buffer material layer 301 comprises an oxide containing indium, and after the remaining filling layer is removed, the exposed part of the buffer material layer is removed, so that the risk of diffusion of the buffer material layer into the subsequently formed dielectric layer can be reduced, thereby ensuring the insulation performance of the dielectric layer.

In some other examples, as shown in FIG. 4H, the buffer material layer 301 directly forms the buffer layer 301″.

In some other examples, after the remaining filling layer is removed, the exposed buffer material layer 310 is not removed and the entire buffer material layer 310 is retained, and all the buffer material layer 310 directly forms the final buffer layer. In this case, the buffer layer is also located between the dielectric layer and the conductive layer. It can be understood that the buffer material layer can achieve an effect of supporting when it is entirely retained, thereby further strengthening the capacitor.

In some examples, the buffer layer 301″ and the conductive layer 302 together form a first electrode 205′.

It should be noted that FIG. 4G and FIG. 4H are two different solutions for whether to remove the exposed buffer material layer, and only the solution in FIG. 4G is illustrated below to describe the following manufacturing process.

As shown in FIG. 4I, a dielectric layer 207 is formed on a side of the first electrode 205′ close to the buffer layer.

In some examples, the dielectric layer 207 may be conformal to the structure after the filling layer is removed, that is, the dielectric layer 207 may cover the exposed surface of the first electrode 205′ and the exposed surface of the supporting layer 202′. In this way, a larger surface area of the dielectric layer can be obtained, thereby facilitating obtaining a larger capacitance capacity.

In some examples, the dielectric layer has a dielectric constant greater than 3.9. For example, the material of the dielectric layer may comprise one or more of aluminum oxide (Al₂O₃), zirconium oxide (ZrO₂), and hafnium oxide (HfO₂).

In some examples, the dielectric layer 207 may be formed by a deposition process, such as an atomic layer deposition process.

Next, a second electrode of the capacitor is formed. In some examples, forming the second electrode comprises: depositing a conductive material on a side of the dielectric layer away from the first electrode to form the second electrode.

As shown in FIG. 4J, a second electrode 208 of the capacitor is formed on a side of the dielectric layer 207 away from the first electrode 205′.

In some examples, the second electrode 208 may cover a side of the dielectric layer 207 away from the first electrode 205′, and the second electrode may have an irregular shape, for example, the second electrode may fill the entire void space regions of the semiconductor structure after the filling layer is removed and the dielectric layer is formed. As such, the capacitor may obtain a larger capacitance capacity.

In some examples, the material of the second electrode 208 may comprise, but is not limited to, tungsten. In some examples, the material forming the second electrode 208 may comprise silicon germanium (SiGe) and tungsten. In some examples, the second electrode 208 may be formed by a deposition process.

It can be understood that, in the process of forming the second electrode, the solution of the buffer layer is not adopted, and the roughness of the surface of the second electrode is greater than the roughness of the surface of the conductive layer of the first electrode.

According to the examples of the present disclosure, by forming a material comprising the oxide containing the indium with a small particle size, concaves on the rough surface can be well filled before forming the conductive layer stacked on the buffer layer, so that the conductive layer has a small surface roughness. The conductive layer with a small surface roughness is conducive to optimizing the equivalent circuit of the capacitor electrode, thereby improving the electric leakage problem of the capacitor.

An example of the present disclosure further provides a capacitor, as shown in FIG. 4J, the capacitor comprises: a dielectric layer 207; a first electrode 205′ and a second electrode 208 located on two sides of the dielectric layer respectively; the first electrode 205′ comprises a conductive layer 302 and a buffer layer 301″ stacked together, and a material of the buffer layer 301″ comprises an oxide containing indium; and the buffer layer 301″ covers at least part of a surface of the conductive layer 302.

Each structural feature of the capacitor in some examples and below may be understood with reference to each structure of the capacitor involved in the manufacturing method of the capacitor described above.

In some examples, the buffer layer 301″ comprises a first surface and a second surface opposite to each other; the first surface is in contact with the conductive layer; and a roughness of the first surface is less than a roughness of the second surface.

In some examples, the conductive layer 302 has a third surface and a fourth surface opposite to each other; the buffer layer 301″ covers at least part of the third surface; and a roughness of the third surface is less than or equal to a roughness of the fourth surface.

In some examples, the first surface, the second surface, the third surface, and the fourth surface may be understood with reference to the first surface, the second surface, the third surface, and the fourth surface in FIGS. 5C and 5D.

In some examples, a material of the buffer layer 301″ comprises at least one of indium oxide, indium tin oxide, indium gallium oxide, indium gallium tin oxide, indium zinc oxide, indium gallium zinc oxide, or indium tin zinc oxide.

In some examples, the material of the conductive layer 302 comprises titanium nitride.

In some examples, the first electrode 205′ and the connection structure 201′ are stacked together; and the buffer layer 301″ is located between the connection structure 201′ and the conductive layer 302.

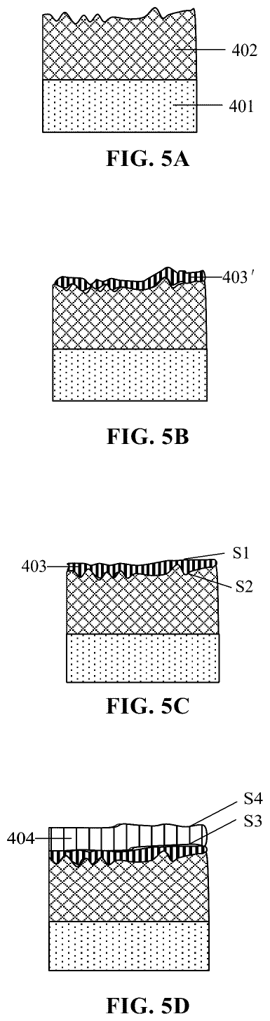

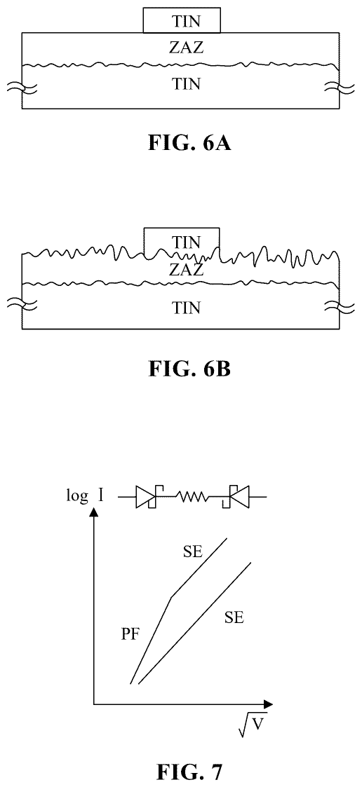

FIG. 8A is a schematic diagram of a layout of a connection structure comprising a capacitor according to examples of the present disclosure; and FIG. 8B is a partial enlarged view corresponding to the dashed box in FIG. 8A.

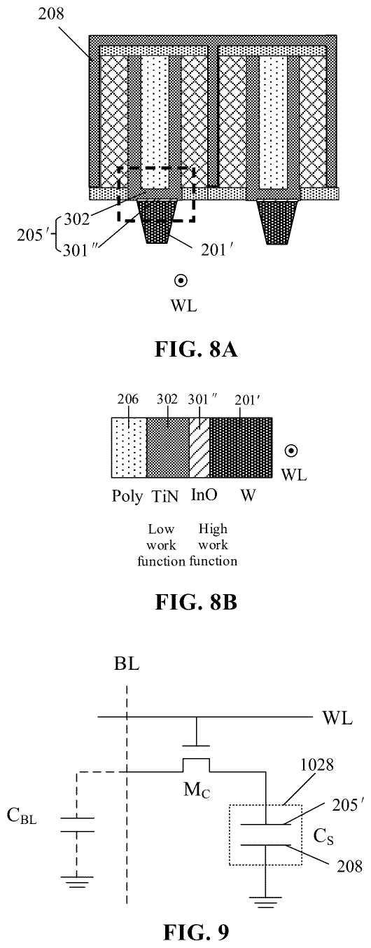

In some examples, the work function of the buffer layer 301″ is higher than the work function of the conductive layer 320. In other words, in the examples of the present disclosure, as shown in FIGS. 8A and 8B, the buffer layer 301″ and the conductive layer 320 form a dual work function electrode, and a low built-in electric field may be formed between the word line WL and the capacitor and may inhibit current leakage, thereby improving the leakage current of the capacitor. One end of the buffer layer 301″ with the high work function is connected to the word line electrode, and the word line forms a high threshold voltage, thereby forming a lower electric field to reduce the height of the memory cell, which is beneficial to the overall process integration. Based on this, as shown in FIG. 9, in some examples, the first electrode is configured to be coupled to the word line WL through the transistor M_{c}.

It should be noted that the second electrodes of the two capacitors shown in FIG. 8A are connected together, which is consistent with that one electrode of the plurality of capacitors in the memory cell array of FIG. 1 may be connected to the peripheral circuit through the common plate, while in the second electrode shown in FIG. 2H and FIG. 4J, due to the limited size of the figures, the part of the second electrode on both sides connected to the common plate on the top is not shown, and the second electrodes on both sides in FIG. 2H and FIG. 4J may both be connected to the common plate at the top.

In some examples, the material of the buffer layer 301″ comprises indium oxide, and the material of the conductive layer comprises titanium nitride. The work function of indium oxide is 4.5-4.8 eV, and its resistivity is 0.3*10-3 μΩ·cm; and the work function of titanium nitride is 3.18 eV, and its resistivity is 10-3 μΩ·cm. The work function of the indium oxide is higher than the work function of the titanium nitride and the resistivity of the indium oxide is lower than the resistivity of the titanium nitride. In this way, it is possible to achieve an electrode with dual work functions without increasing the resistivity of the electrode.

According to the example of the present disclosure, the electric leakage problem of the capacitor is improved by reducing the roughness of the surface of the first electrode, while the dual work function electrode is formed on the first electrode, and the electric leakage problem of the capacitor is further improved.

In some examples, the first electrode 205′ extends through the supporting layer; and the buffer layer 301″ is located between the supporting layer 202′ and the conductive layer 302.

In some examples, as shown in FIG. 4H, the buffer layer 301″ is also located between the dielectric layer 207 and the conductive layer 302.

In some examples, a thickness of the buffer layer ranges from 1 nm-20 nm.

The example of the present disclosure further provides a capacitor, comprising: a dielectric layer; a first electrode and a second electrode located on two sides of the dielectric layer respectively, wherein the first electrode comprises a conductive layer and a buffer layer that are stacked together, the buffer layer has a first surface and a second surface opposite to each other; the first surface is in contact with the conductive layer, and a roughness of the first surface is less than a roughness of the second surface.

In some examples, the first surface and the second surface may be understood with reference to the first surface and the second surface in FIG. 5C. In some examples, a difference between the roughness of the second surface and the roughness of the first surface is greater than a preset difference. In some examples, a range of the first preset difference is: 0.3-0.5 nm. For example, the preset difference is 0.3 nm, 0.4 nm, or 0.5 nm.

In some examples, the material of the buffer layer comprises an oxide containing indium.

In some examples, the material of the buffer layer comprises at least one of indium oxide, indium tin oxide, indium gallium oxide, indium gallium tin oxide, indium zinc oxide, indium gallium zinc oxide, or indium tin zinc oxide.

In the examples of the present disclosure, the material of the buffer layer may further comprise other materials that may reduce surface roughness of the conductive layer, which is not limited in the examples of the present disclosure.

In some examples, the conductive layer has a third surface and a fourth surface opposite to each other; the buffer layer covers at least part of the third surface; and a roughness of the third surface is less than or equal to a roughness of the fourth surface.

In some examples, the third surface and the fourth surface may be understood with reference to the third surface and the fourth surface of FIG. 5D.

In some examples, a roughness of a surface of the second electrode is greater than a roughness of a surface of the conductive layer of the first electrode.

In some examples, in a process of forming the second electrode, the solution of the buffer layer is not adopted, and a roughness of a surface of the second electrode is greater than a roughness of a surface of the conductive layer of the first electrode.

The examples of the present disclosure further provide a memory device, comprising: a capacitor provided in an example of the present disclosure; and a transistor coupled to a capacitor.

In some examples, the memory device may comprise a dynamic random access memory.

In the examples of the present disclosure, the memory device may be understood with reference to the dynamic random access memory 100 in FIG. 1, which will not be detailed here.

In some examples, the memory device further comprises a connection structure; the connection structure is located between the capacitor and the transistor; and the buffer layer is located between the connection structure and the conductive layer.

In some examples, the connection structure may be understood with reference to the conductive structure 1064 in FIG. 1.

In some examples, the memory device further comprises a supporting layer; the first electrode extends through the supporting layer; and the buffer layer is located between the supporting layer and the conductive layer.

In some examples, the support layer comprises a plurality of supporting layers stacked together and spaced apart from each other; and the buffer layer is located between the plurality of support layers and the conductive layer.

In some examples, the memory device further comprises: a word line and a bit line, wherein a gate of the transistor is coupled to the word line; one of a source and a drain of the transistor is coupled to the first electrode; and the other one of the source and the drain of the transistor is coupled to the bit line.

In some examples, the transistor may be understood with reference to the vertical transistor 1026 in FIG. 1.

According to the examples of the present disclosure, the electric leakage problem of the capacitor is improved by forming the interface buffer layer to reduce the surface roughness.

In other implementations, the electric leakage problem of the capacitor may be improved by optimizing the sense amplifier and the process of the bit line from the design end to improve the sense margin.

In some other implementations, the electric leakage problem of the capacitor may be improved by changing the composition of the dielectric layer in the capacitor or the location of the composition, such as adding aluminum oxide (Al₂O₃) and material with a high bandgap.

In some other implementations, the electric leakage problem of the capacitor may be improved by increasing the thickness of the dielectric layer or subsequent thermal treatment to optimize the crystalline ratio or the crystalline type of the dielectric layer.

In some other examples, the electric leakage of the capacitor may be improved by surface treatment, such as plasma treatment before the growth of the dielectric layer, or by reducing the proportion of oxygen vacancies.

In some other examples, the electrode material may be changed to improve overall electric leakage.

It may be understood that, the solution for improving electric leakage of the capacitor by forming the interface buffer layer to reduce the surface roughness in the examples of the present disclosure may be combined with one or more other solutions for solving the electric leakage problem of the capacitor without conflict.

It should be noted that, the technical solutions described in the examples of the present disclosure may be arbitrarily combined without conflict.

The protection scope of the present disclosure is not limited by implementations of the present disclosure. Variations or replacements that may be readily conceived by any person skilled in the art within the technical scope of the present disclosure should be encompassed within the protection scope of the present disclosure. Therefore, the protection scope of the present disclosure should be defined by the protection scope of the claims.

What is claimed is:

1. A capacitor, comprising:
a dielectric layer; and
a first electrode and a second electrode located on two sides of the dielectric layer respectively, wherein the first electrode comprises a conductive layer and a buffer layer that are stacked together, a material of the buffer layer comprises an oxide containing indium, and the buffer layer covers at least part of a surface of the conductive layer.

2. The capacitor of claim 1, wherein the buffer layer comprises a first surface and a second surface opposite to each other, the first surface is in contact with the conductive layer, and a roughness of the first surface is less than a roughness of the second surface.

3. The capacitor of claim 1, wherein the conductive layer has a third surface and a fourth surface opposite to each other, the buffer layer covers at least part of the third surface, and a roughness of the third surface is less than or equal to a roughness of the fourth surface.

4. The capacitor of claim 1, wherein the material of the buffer layer comprises at least one of indium oxide, indium tin oxide, indium gallium oxide, indium gallium tin oxide, indium zinc oxide, indium gallium zinc oxide, or indium tin zinc oxide.

5. The capacitor of claim 1, wherein a material of the conductive layer comprises titanium nitride.

6. The capacitor of claim 1, wherein the first electrode and a connection structure are stacked together, and the buffer layer is located between the connection structure and the conductive layer.

7. The capacitor of claim 1, wherein the first electrode extends through a supporting layer, and the buffer layer is located between the supporting layer and the conductive layer.

8. The capacitor of claim 7, wherein the buffer layer is further located between the dielectric layer and the conductive layer.

9. The capacitor of claim 1, wherein a work function of the buffer layer is higher than a work function of the conductive layer.

10. The capacitor of claim 9, wherein the first electrode is configured to be coupled to a word line through a transistor.

11. The capacitor of claim 1, wherein a thickness of the buffer layer ranges from 1 nm to 20 nm.

12. A capacitor, comprising:
a dielectric layer; and
a first electrode and a second electrode located on two sides of the dielectric layer respectively, wherein the first electrode comprises a conductive layer and a buffer layer that are stacked together, and wherein
the buffer layer has a first surface and a second surface opposite to each other, the first surface is in contact with the conductive layer, and a roughness of the first surface is less than a roughness of the second surface.

13. The capacitor of claim 12, wherein a material of the buffer layer comprises an oxide containing indium.

14. The capacitor of claim 12, wherein the conductive layer has a third surface and a fourth surface opposite to each other, the buffer layer covers at least part of the third surface, and a roughness of the third surface is less than or equal to a roughness of the fourth surface.

15. The capacitor of claim 12, wherein a roughness of a surface of the second electrode is greater than a roughness of a surface of the conductive layer of the first electrode.

16. A memory device, comprising:
a capacitor, comprising:
a dielectric layer; and
a first electrode and a second electrode located on two sides of the dielectric layer respectively, wherein the first electrode comprises a conductive layer and a buffer layer that are stacked together, a material of the buffer layer comprises an oxide containing indium, and the buffer layer covers at least part of a surface of the conductive layer; and
a transistor coupled to the capacitor.

17. The memory device of claim 16, further comprising a connection structure, wherein
the connection structure is located between the capacitor and the transistor, and
the buffer layer is located between the connection structure and the conductive layer.

18. The memory device of claim 16, further comprising a supporting layer, wherein
the first electrode extends through the supporting layer, and
the buffer layer is located between the supporting layer and the conductive layer.

19. The memory device of claim 18, wherein the supporting layer comprises a plurality of supporting layers stacked together and spaced apart from each other, and
the buffer layer is located between the plurality of supporting layers and the conductive layer.

20. The memory device of claim 16, further comprising a word line and a bit line, wherein
a gate of the transistor is coupled to the word line,
one of a source and a drain of the transistor is coupled to the first electrode, and
the other one of the source and the drain of the transistor is coupled to the bit line.
